(19) United States
(12) Patent Application Publication
(10) Pub. No.: US 2012/0051509 A1
(43) Pub. Date: Mar. 1, 2012

(54) Grid for radiography and manufacturing method thereof, and radiation imaging system

(75) Inventor: Yasuhisa Kaneko, Kanagawa (JP)

(73) Assignee: FUJIFILM Corporation, Tokyo (JP)

(21) Appl. No.: 13/137,379

(22) Filed: Aug. 10, 2011

(30) Foreign Application Priority Data
Aug. 30, 2010 (JP) 2010-192358

(51) Int. Cl. G21K 1/00; G01N 23/04; H01L 31/18

(52) U.S. Cl. 378/62; 438/69; 378/145; 257/E31.092

(57) ABSTRACT

To produce a grid for radiography, grooves with a high aspect ratio are formed in an X-ray transparent substrate, and a colloidal gold solution is dripped into the grooves in such an amount that the colloidal gold solution does not overflow the grooves. The applied colloidal gold solution flows into the grooves by capillarity. The X-ray transparent substrate is heated from beneath by a laser beam at a portion charged with the colloidal gold solution. Thus, the colloidal gold solution is dried with leaving colloidal gold particles behind. The charging and drying of the colloidal gold solution are repeated, until the grooves are filled with the colloidal gold particles. The grooves and the colloidal gold particles compose X-ray absorbing portions of the grid.

### BACKGROUND OF THE INVENTION

1. Field of the Invention

The present invention relates to a grid used in radiography, a manufacturing method of the grid, and a radiation imaging system using the grid.

2. Description Related to the Prior Art

A radiation imaging system using the Talbot effect is devised to perform a type of radiation phase imaging, for obtaining an image (hereinafter called phase contrast image) based on phase change (angle change) of a radiation beam by passing through a test object. For example, an X-ray imaging system using an X-ray beam as the radiation beam has a first grid disposed behind the test object to be imaged, a second grid disposed downstream from the first grid in an X-ray beam direction, and an X-ray image detector disposed behind the second grid. The second grid is situated away from the first grid by a specific distance (Talbot distance), which is determined by a grid pitch of the first grid and a wavelength of the X-ray beam. The X-ray beam passes through the first grid, and forms a self image (fringe image) by the Talbot effect at the position of the second grid. The self image is modulated by interaction (phase change) between the test object and the X-ray beam.

In the above X-ray imaging system, the second grid is superimposed on the self image of the first grid, to obtain a fringe image with modulated intensity. Based on change (phase shift) of the fringe image by the test object, a phase contrast image is obtained. This method is called a fringe scanning method. More specifically, in this method, an image is captured at each scan position, while the second grid is translationally moved (scanned) relative to the first grid in a direction approximately parallel to a surface of the first grid and approximately orthogonal to a grid direction of the first grid by a scan pitch that is an integral submultiple of the grid pitch. Then, a differential phase image (corresponding to angular distribution of the X-ray beam refracted by the test object) is obtained from a phase shift amount of intensity variation of pixel data of each pixel obtained by the X-ray image detector with respect to the scan positions. Integrating the differential phase image along a fringe scanning direction allows obtainment of the phase contrast image of the test object.

The first and second grids have such configuration that X-ray absorbing portions extending in a direction orthogonal to the X-ray beam direction are arranged at a predetermined pitch into stripes in a direction orthogonal to both of the X-ray beam direction and the extending direction. The arrangement pitch of the X-ray absorbing portions is determined from a distance between an X-ray focus and the first grid and a distance between the first and second grids, and is approximately 2 to 20 μm. Each of the X-ray absorbing portions of the second grid requires a high aspect ratio, i.e. a thickness of the order of 100 μm in the X-ray beam direction, for the purpose of acquiring high X-ray absorptivity.

In a well-known conventional method for manufacturing a grid for phase imaging, formation of a resist pattern of grooves with a low aspect ratio and embedment of gold paste or the like into the grooves are repeated in a stacked manner, to form X-ray absorbing portions with a high aspect ratio (refer to Japanese Patent Laid-Open Publication No. 2009-282322, for example). Also, there is a known method in which grooves with a high aspect ratio are formed in an X-ray transparent substrate, and an X-ray absorbent material such as gold nanopaste is charged into the grooves to form X-ray absorbing portions (refer to US Patent Application Publication No. 2010/0246764).

In the Japanese Patent Laid-Open Publication No. 2009-282322, the gold paste is embedded into the grooves formed in the resist pattern. However, the resist pattern is formed in a thin film layer, and the aspect ratio of the groove formed in the thin film layer is 1 or less, at most. Thus, to obtain the X-ray absorbing portions with the high aspect ratio, it is necessary to repeat the formation of the resist pattern and the embedment of the gold paste a quite number of times, and requires much time. In addition, according to the Japanese Patent Laid-Open Publication No. 2009-282322 and the US Patent Application Publication No. 2010/0246764, the gold paste is used as the X-ray absorbent material. Paste means a material having a viscosity over 1 PaS, generally having a viscosity of 100 to 1000 PaS. Therefore, it is difficult to embed the gold paste having a high viscosity into the minute grooves having a width of several μm to a depth of the order of 100 μm, without occurrence of a void. If the void occurs in the embedment, the X-ray absorptivity of the X-ray absorbing portions is reduced. This may cause the grid to fail to have predetermined properties.

### SUMMARY OF THE INVENTION

An object of the present invention is to provide a grid for radiography formed easily and precisely.

Another object of the present invention is to provide a manufacturing method of the grid by which an X-ray absorbent material is easily and tightly embedded into grooves with a high aspect ratio.

To achieve the above and other objects, a grid for radiography according to the present invention includes a plurality of radiation absorbing portions made of colloidal radiation absorptive particles and a plurality of radiation transmitting portions for passing radiation.

It is preferable that the colloidal particles are embedded in a plurality of grooves provided in a radio-transparent substrate. The grid may further include a plurality of bridge portions for connecting two or more partition walls, each of which is provided between the grooves as a partition. The radiation absorbing portions may be provided on the radio-transparent substrate. The colloidal particles are preferably colloidal metal particles or colloidal non-metal inorganic particles.

A manufacturing method of a grid for radiography includes the steps of forming a plurality of grooves and a plurality of bridge portions in a radio-transparent substrate, charging a colloidal solution containing colloidal radiation absorptive particles into the grooves without overflowing the grooves, heating the substrate at least at a portion of the grooves charged with the colloidal solution and drying the colloidal solution to leave the colloidal particles behind in the grooves, and repeating the charging step and the heating step until the grooves are filled with the colloidal particles.

It is preferable that in the charging step, the colloidal solution is applied to the substrate in such an amount as not to overflow the grooves, so that all the colloidal solution flows into the grooves.

The manufacturing method may further include the step of subjecting the substrate to a chemical treatment to improve wettability of the substrate, after the forming step of the grooves and the bridge portions.

In the heating step, a laser beam is preferably applied to the substrate at a rear surface opposite to a front surface formed with the grooves.

It is preferable that between the colloidal solution to be charged into the grooves for a first time and the colloidal solution to be charged into the grooves for a second or later time, at least one of a viscosity, a diameter of the colloidal particles, a percentage content of the colloidal particles is different.

The manufacturing method may further include the step of removing the colloidal particles deposited on the substrate by the repeating step. The manufacturing method may further include the step of forming a liquid repellent film on a front surface of the substrate to render the front surface repellent to the colloidal solution, after the forming step of the grooves and the bridge portions.

A radiation imaging system according to the present invention includes a radiation source for emitting radiation, a first grid for producing a fringe image by passing the radiation, a second grid for applying intensity modulation to the fringe image in each of plural relative positions having different phases with respect to a periodic pattern of the fringe image, a third grid disposed between the radiation source and the first grid for partly shielding the radiation emitted from the radiation source to form a plurality of linear light sources, and a radiation image detector for detecting the fringe image after being subjected to the intensity modulation by the second grid in each of the relative positions. In the radiation imaging system, a grid of the present invention is applied to at least one of the first to third grids.

The grid of the present invention uses the colloidal particles with low stress in the radiation absorbing portions. Thus, the grid is flexible and resists damage. The radiation absorbing portions may be embedded into the grooves provided in the radio-transparent substrate, or may be provided on the substrate. Thus, the grid is formed into arbitrary configuration. In the case of charging the colloidal particles into the grooves, the bridge portions for connecting the partition walls facilitate improving the strength of the grid. As the colloidal particles, the colloidal metal particles or the colloidal non-metal inorganic particles are usable. This improves radiation absorptivity of the grid.

In the manufacturing method of the grid according to the present invention, since the colloidal particles are charged into the grooves by repetition of the charging and heating of the colloidal solution, it is possible to prevent occurrence of void or shim in the grooves. Also, the bridge portions for connecting the partition walls across the groove can prevent occurrence of sticking, which tends to occur during the drying step of the colloidal solution.

The colloidal solution is charged into the grooves with use of capillarity. Thus, the colloidal solution can be appropriately charged into the grooves, even if the grooves have a high aspect ratio. Since the substrate is subjected to the chemical treatment to improve its wettability, the colloidal solution can be certainly charged into the grooves. Furthermore, use of the laser beam allows heating of the substrate only at the portion charged with the colloidal solution.

Between the colloidal solution charged in a first time and the colloidal solution charged in a second or later time, properties such as the viscosity are different. Therefore, it is possible to charge the colloidal solution with the optimal properties, in accordance with the number of charging.

The colloidal particles deposited on the front surface of the substrate are removed. This increases transmittance of the radiation through the radiation transmitting portions, and hence improves performance of the grid. Provision of the liquid repellent film on the front surface of the substrate inhibits deposition of the colloidal particles on the front surface, and hence prevents reduction in the performance of the grid.

The radiation imaging system using the above grid can take a radiographic image with high image quality.

### BRIEF DESCRIPTION OF THE DRAWINGS

For more complete understanding of the present invention, and the advantage thereof, reference is now made to the following descriptions taken in conjunction with the accompanying drawings, in which:

FIG. 1 is a schematic view of an X-ray imaging system;

FIG. 2A is a top plan view of a second grid;

FIG. 2B is a cross sectional view taken along the line A-A of FIG. 2A;

FIGS. 3A to 3C are explanatory views showing a manufacturing procedure of the second grid;

FIG. 4 is a top plan view of an X-ray transparent substrate in which grooves and bridge portions are formed;

FIGS. 5A to 5D are explanatory views explaining a state in which a step of charging a colloidal metal solution into the grooves of the X-ray transparent substrate is repeated;

FIG. 6 is an explanatory view of division areas of the X-ray transparent substrate;

FIG. 7 is a cross sectional view showing an example of sticking that occurs in drying the colloidal metal solution;

FIG. 8 is a cross sectional view showing examples of void and shim that occur in drying the colloidal metal solution;

FIGS. 9A and 9B are cross sectional views showing an example of removing an X-ray absorbent material deposited on a surface of the X-ray transparent substrate;

FIGS. 10A and 10B are cross sectional views showing an example of a liquid repellent film provided on the surface of the X-ray transparent substrate;

FIG. 11 is a cross sectional view of the thinned X-ray transparent substrate;

FIG. 12 is a cross sectional view of the X-ray transparent substrate in which intermediate portions between the X-ray absorbing portions are removed;

FIG. 13 is a plan view of a large grid composed of plural small grids; and

FIG. 14 is a schematic view of an X-ray imaging system using curved grids.

### DESCRIPTION OF THE PREFERRED EMBODIMENTS

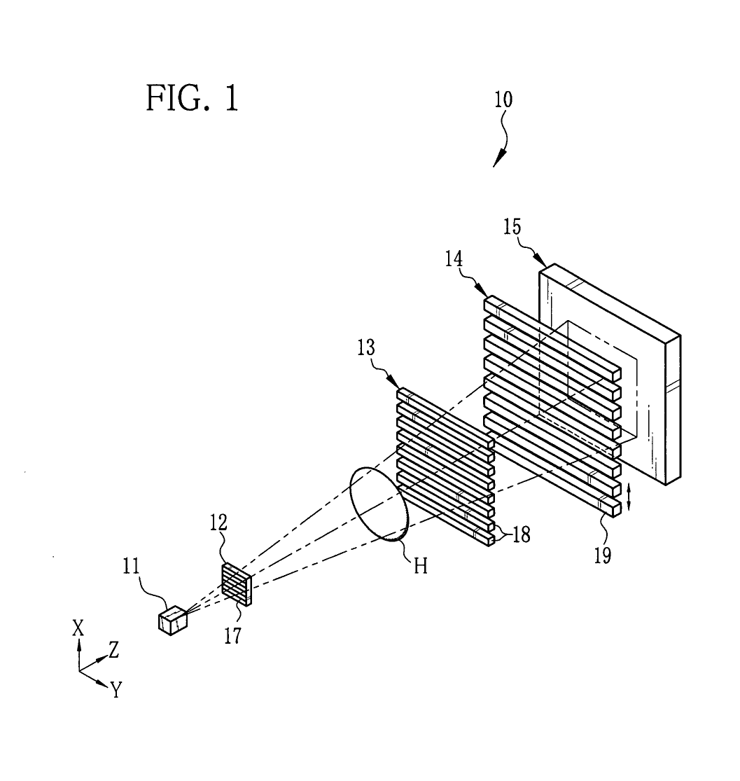

As shown in FIG. 1, an X-ray imaging system 10 according to the present invention is constituted of an X-ray source 11, a source grid 12, a first grid 13, a second grid 14, and an X-ray image detector 15. The X-ray source 11 applies an X-ray beam to a test object H disposed in a Z direction. The source grid 12 is opposed to the X-ray source 11 in the Z direction. The first grid 13 is disposed in parallel with the source grid 12 at a predetermined distance away from the source grid 12 in the Z direction. The second grid 14 is disposed in parallel with the first grid 13 at another predetermined distance away from the first grid 13 in the Z direction. The X-ray image detector 15 is opposed to the second grid 14. As the X-ray image detector 15, a flat panel detector (FPD) having semiconductor circuitry is used, for example.

The source grid 12, the first grid 13, and the second grid 14 are X-ray absorption grids having plural X-ray absorbing portions 17, 18, and 19, respectively. The X-ray absorbing portions 17, 18, and 19 extend linearly in a Y direction orthogonal to the Z direction, and are periodically arranged at a predetermined pitch into stripes along an X direction orthogonal to both the Z and Y directions. In the grids 12, 13, and 14, the X-ray absorbing portions 17, 18, and 19 absorb the X-ray beam, while X-ray transmitting portions provided between the X-ray absorbing portions 17, 18, and 19 transmit the X-ray beam.

Taking the second grid 14 as an example, the configuration of the X-ray absorbing portions will be described. Note that, the source grid 12 and the first grid 13 have configuration similar to that of the second grid 14 except for the width, pitch, thickness in an X-ray beam direction, and the like of the X-ray absorbing portions 17 and 18. Thus, detailed description of the source grid 12 and the first grid 13 will be omitted.

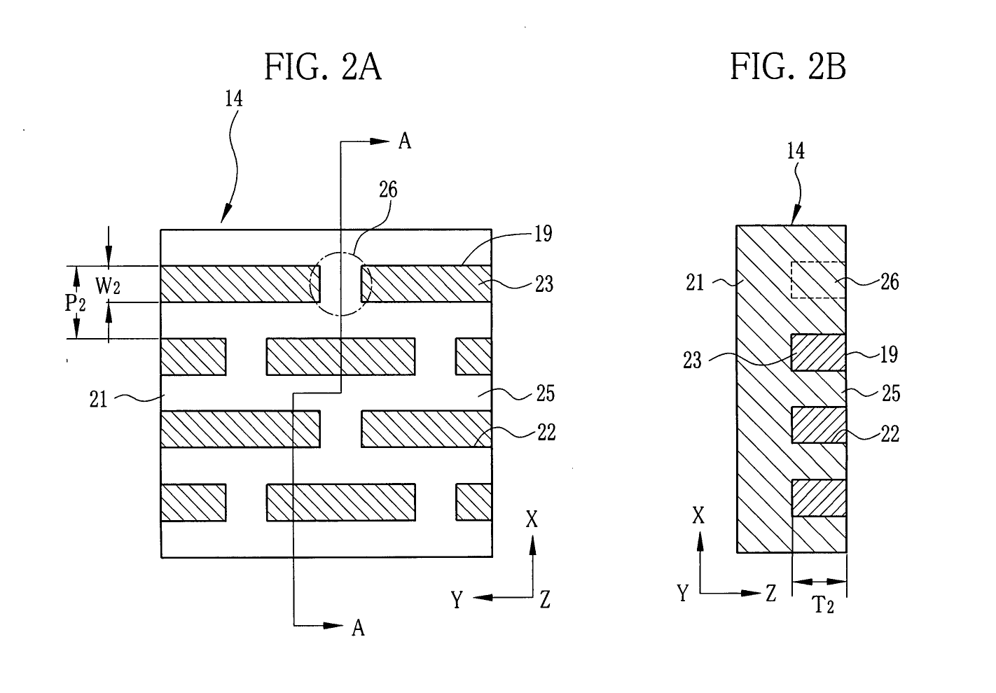

FIG. 2A is a top plan view of the second grid 14 viewed from the side of the X-ray image detector 15. FIG. 2B shows a cross section taken along the line A-A of FIG. 2A. The second grid 14 is composed of an X-ray transparent substrate 21 made of an X-ray transparent material such as silicon, plural grooves 22 extending in the Y direction and arranged at a predetermined pitch in the X direction, an X-ray absorbent material 23 charged into each groove 22. The groove 22 and the X-ray absorbent material 23 compose the X-ray absorbing portion 19.

The width W₂ and pitch P₂ of the X-ray absorbing portions 19 are determined from the distance between the source grid 12 and the first grid 13, the distance between the first grid 13 and the second grid 14, a pitch of the X-ray absorbing portions 18 of the first grid 13, and the like. The X-ray absorbing portions 19 have a width W₂ of approximately 2 to 20 μm, and a pitch P₂ of approximately 4 to 40 μm. It is preferable that the thickness T₂ of the X-ray absorbing portions 19 in the Z direction is as thick as possible, for the sake of obtaining high X-ray absorptivity. In reality, the X-ray absorbing portions 19 has a thickness T₂ of the order of 100 μm, for example, in consideration of vignetting of the cone-shaped X-ray beam emitted from the X-ray source 11. In this embodiment, the X-ray absorbing portions 19 have a width W₂ of 2.5 μm, a pitch P₂ of 5 μm, and a thickness T₂ of 100 μm, by way of example.

A plurality of partition walls 25, which partition the grooves 22 of the X-ray transparent substrate 21 in the X direction, function as the X-ray transmitting portions. Across each groove 22, bridge portions 26 are provided to connect the next two partition walls 25 for reinforcement. The width of the bridge portion 26 in the Y direction is preferably the same as or larger than the width of the partition wall 25 in the X direction. The arrangement pitch of the bridge portions 26 in the Y direction is preferably five or more times larger than the width W₂ of the groove 22, for example. This is because if the arrangement pitch is too short, an increased number of the bridge portions 26 bring about reduction in the X-ray absorptivity of the X-ray absorbing portion 19. As shown in FIG. 2A, the bridge portions 26 are arranged in a staggered manner, such that the bridge portion 26 of one groove 23 is not aligned with that of the next groove 23 in the X direction. Note that, the layout of the bridge portions 26 is not limited to the above. The bridge portions 26 may be arranged in a line parallel to the X direction, or in a line oblique in the Y direction. In the case of considering reduction in the X-ray absorptivity by the bridge portions 26, the bridge portions 26 are preferably arranged at random. The bridge portion 26 lies from top to bottom of the groove 22, in other words, the bridge portion 26 extends across the whole depth of the groove 22. However, the bridge portion 26 may be provided only in a top portion, a middle portion, or a bottom portion of the groove 22. As a way of forming the bridge portion 26, after the grooves 22 are formed continuously in the Y direction and charged with the X-ray absorbent material 23, a separate member may be disposed so as to partly connect a top surface of one partition wall 25 to that of the next partition wall 25.

The X-ray absorbent material 23 contains plural types of X-ray absorptive metals, and is principally made of colloidal gold particles, for example. The colloidal gold particles are charged into the grooves 22 in a state of a colloidal gold solution, that is, in a state of being dispersed in a solution. The colloidal gold solution is heated and dried in the grooves 22, so that the colloidal gold particles remaining in the grooves 22 form the X-ray absorbing portions 19. The colloidal gold solution contains copper (Cu), bismuth (Bi), and the like, in addition to the colloidal gold particles. These plural types of X-ray absorptive metals remain in the grooves 22 together with the colloidal gold particles, and hence improve the X-ray absorptivity of the X-ray absorbing portions 19. The colloidal gold particles have low stress, because the particles are bonded more weakly than those bonded by gold plating or the like. Thus, if an external force is exerted on the second grid 14, the colloidal gold particles can absorb the external force, and the second grid 14 is hard to damage. Moreover, the colloidal gold particles render the second grid 14 flexible. The flexibility can make a grid into convergence configuration. In addition, the colloidal gold particles are resistant to diffusion. If the gold of the X-ray absorbing portions 19 is diffused into the X-ray transparent substrate 21, both the X-ray absorptivity of the X-ray absorbing portions 19 and the X-ray transparency of the X-ray transparent substrate 21 are reduced, and the performance of the second grid 14 is degraded. The colloidal gold particles, however, hardly cause such degradation.

Taking the second grid 14 as an example, a manufacturing method of a grid for radiography according to the present invention will be described. Note that, since the source grid 12 and the first grid 13 are manufactured by a same or similar method, detailed description thereof will be omitted.

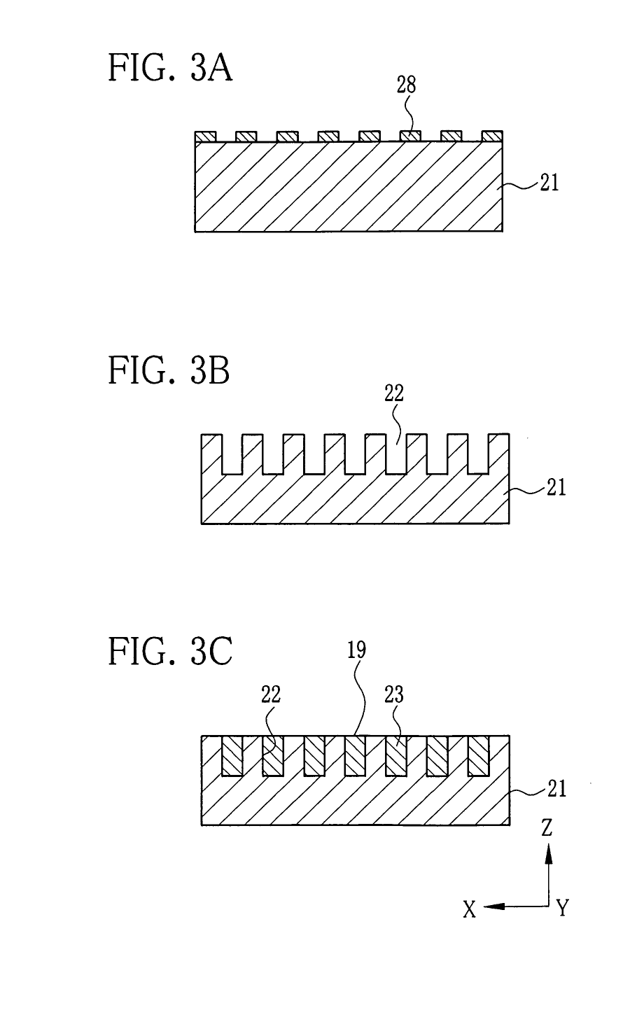

As shown in FIG. 3A, in a first step of the manufacture of the second grid 14, etching masks 28 are formed on a top surface of the silicon X-ray transparent substrate 21 using a conventional photolithography technique. The etching masks 28 are formed into a stripe pattern and a bridge pattern. The stripe pattern is composed of the long etching masks 28 that linearly extend in the Y direction and are arranged periodically at a predetermined pitch in the X direction. The bridge pattern is composed of the short etching masks 28 each of which connects the next two long etching masks 28 of the stripe pattern, to form the bridge portions 26.

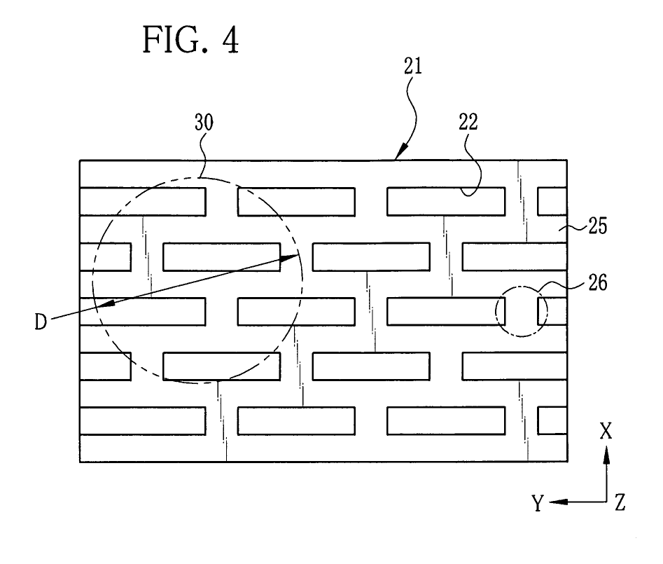

In the next step, as shown in FIG. 3B, the plural grooves 22 are formed in the X-ray transparent substrate 21 by dry etching using the etching masks 28. Since the grooves requires a high aspect ratio having a width of several μm and a depth of the order of 100 μm, for example, Bosch process, cryo process, or the like is used in the dry etching to form the grooves 22. In another case, a photosensitive resist may be used instead of the silicon substrate, and the grooves 22 may be formed by exposure to synchrotron radiation. FIG. 4 shows the X-ray transparent substrate 21 having the plural grooves 22 and the bridge portions 26 formed.

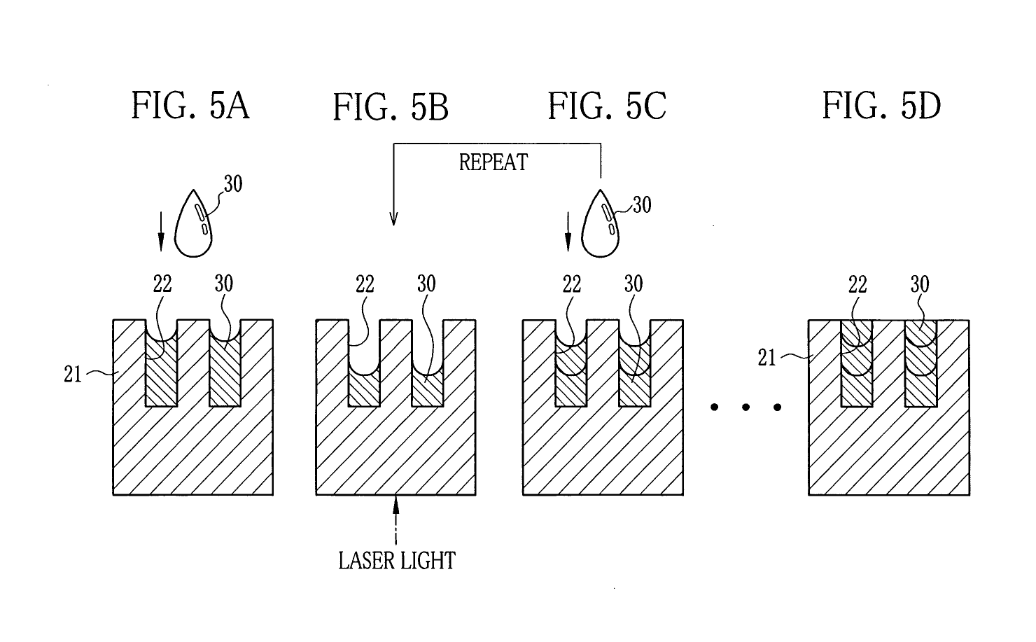

In the next step, as shown in FIG. 3C, the X-ray absorbent material 23 is embedded into the grooves 22 of the X-ray transparent substrate 21 to form the X-ray absorbing portions 19. In the embedment, as shown in FIGS. 5A to 5D, both application of the colloidal gold solution to the surface of the X-ray transparent substrate 21 on the side of the grooves 22 and drying the colloidal gold solution are repeated. The used colloidal gold solution contains the colloidal gold particles having a size of the order of 10 to 1000 Å dispersed in an arbitrary homogeneous solvent. The colloidal gold solution preferably has a gold content of the order of 50 mass % and a viscosity of 1 PaS or less, for example. Instead of the colloidal gold solution, a colloidal platinum solution may be used, or a colloidal solution into which plural X-ray absorptive metals e.g. gold and platinum are mixed may be used.

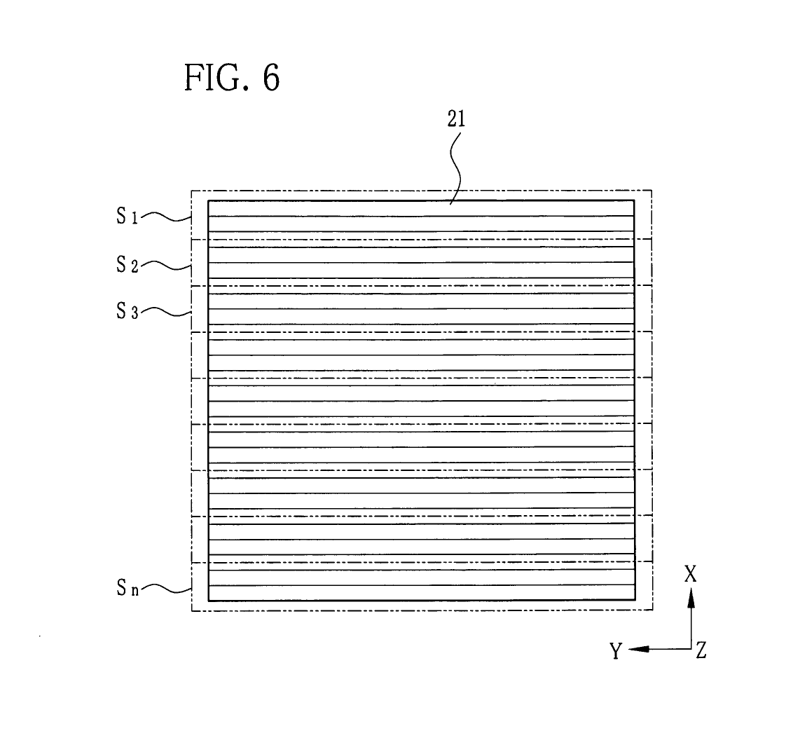

As shown in FIG. 5A, a colloidal gold solution 30 is applied to the X-ray transparent substrate 21 by a device for dripping or spraying a minute liquid droplet, such as an inkjet head, a sprayer, or a dispenser. In the case of using the inkjet head or the dispenser, as shown in FIG. 4, the size D of the droplet of the colloidal gold solution 30 to be applied to the X-ray transparent substrate 21 is 10 to 50 for example. The X-ray transparent substrate 21 is divided into plural areas S1 to Sn in the X direction, as shown in FIG. 6, and the colloidal gold solution 30 is applied to the X-ray transparent substrate 21 from area to area. The colloidal gold solution 30 applied to the X-ray transparent substrate 21 flows into each groove 22 by capillarity. The colloidal gold solution 30 is applied in such an amount as not to overflow the grooves 22. Note that, to ease a flow of the colloidal gold solution 30 into the grooves 22, after the grooves 22 are formed, the X-ray transparent substrate 21 may be subjected to a wettability improving process, including primer process, a UV cleaning, a plasma cleaning, or the like. Note that, the colloidal gold solution 30 may be sprayed by the sprayer on every area S1 to Sn at a time.

As shown in FIG. 5B, after the application of the colloidal gold solution 30 to the X-ray transparent substrate 21, the X-ray transparent substrate 21 is heated to approximately 30° C., for example, at the solution application areas S1 to Sn. The colloidal gold solution 30 is dried in the grooves 22, and only the colloidal gold particles are left in the grooves 22. The X-ray transparent substrate 21 is heated by applying a laser beam from beneath to rear surfaces of the areas S1 to Sn. Note that, a certain time is required by the colloidal gold solution 30 applied to the X-ray transparent substrate 21 for flowing into the bottom of each groove 22. Thus, it is preferable that the X-ray transparent substrate 21 is heated after a lapse of predetermined time from the application of the colloidal gold solution 30.

As shown in FIG. 5B, since the solvent is vaporized in gas form by heating and drying the colloidal gold solution 30, the amount of the colloidal gold particles remaining in each groove 22 is less than the amount of the colloidal gold solution 30 charged thereinto. Therefore, it is necessary to repeat both an additional application step of the colloidal gold solution 30 as shown in FIG. 5C and a heating and drying step of the additionally applied colloidal gold solution 30 as shown in FIG. 5B, until the grooves 22 are filled with the colloidal gold particles as shown in FIG. 5D. The number of repetition of the additional application step and the heating and drying step depends on a percentage content of the colloidal gold particles and the amount of the colloidal gold solution 30 to be charged into the grooves 22 by the single application. In a case where the colloidal gold solution 30 with a percentage content of the colloidal gold particles of 50 mass % is applied at a droplet size of 10 to 50 μm, the additional application step and the heating and drying step are repeated a couple of times.

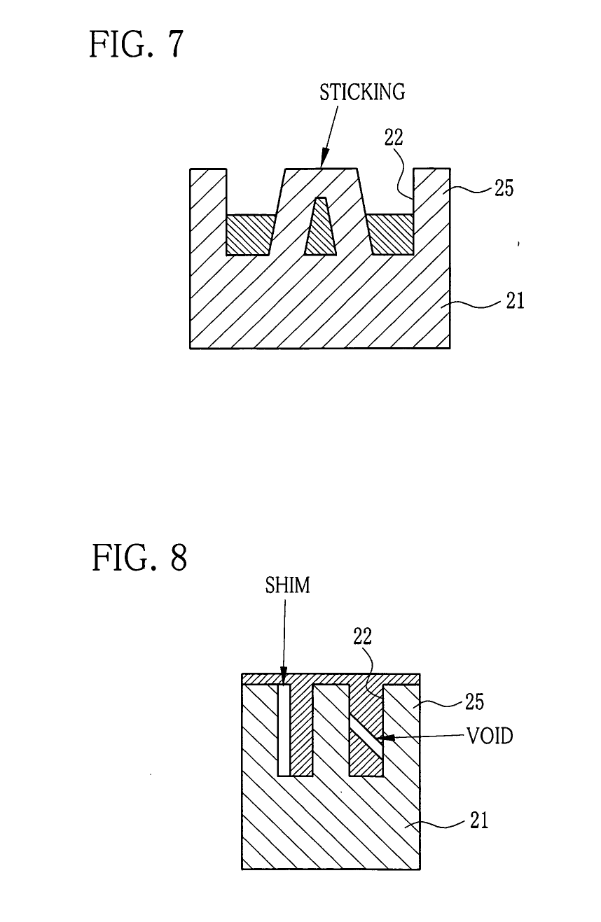

In charging and drying the colloidal gold solution 30 in the grooves 22, sticking sometimes occurs, in which the partition walls 25 of the X-ray transparent substrate 21 fall down and are stuck to each other, as shown in FIG. 7. The sticking is ascribable to that surface tension of the colloidal gold solution 30 pulls the partition walls 25 in drying the colloidal gold solution 30 having a relatively low content of the colloidal gold particles. The occurrence of the sticking causes irregularity in the pitch of the X-ray absorbing portions 19, and variations in the X-ray absorptivity, resulting in degradation in the grid performance. In this embodiment, however, the bridge portions 26 provided across the groove 22 can prevent the occurrence of the sticking.

For the sake of improving throughput for charging the colloidal gold solution 30 into the grooves 22, it is conceivable that a large amount of the colloidal gold solution 30 is applied at a time to the extent that the colloidal gold solution 30 overflows the grooves 22 into the top surface of the X-ray transparent substrate 21, as shown in FIG. 8, and heated and dried. However, in this case, gas is produced in heating and drying the colloidal gold solution 30, and is trapped inside the groove 22. This causes occurrence of a charge defect including a void being a gap between the colloidal gold particles, a shim being a gap between the colloidal gold particles along a side wall of the groove 22, and the like. The void causes reduction in the X-ray absorptivity of the X-ray absorbing portion 19. The shim causes irregularity in the pitch of the X-ray absorbing portions 19. The grid performance is degraded in either case. In this embodiment, however, the occurrence of the void and the shim is prevented, because the colloidal gold solution 30 is charged little by little over several times.

Next, operation of the X-ray imaging system 10 will be described. The X-ray beam emitted from the X-ray source 11 is partly blocked by the X-ray absorbing portions 17 of the source grid 12, to reduce an effective focus size and form many linear light sources (dispersed light sources) in the X direction. When each linear X-ray beam emitted from each of the linear light sources formed by the source grid 12 passes through the test object H, phase difference occurs in the linear X-ray beam. After that, passing through the first grid 13, the linear X-ray beam forms a fringe image into which transmission phase information of the test object H depending on a refractive index and a transmission optical path of the test object H is incorporated. The fringe image of each linear X-ray beam is projected onto the second grid 14. In a position of the second grid 14, the fringe images of every linear X-ray beam are combined. Thus, it is possible to improve the image quality of a phase contrast image without reducing the intensity of the X-ray beam.

A combined fringe image is subjected to intensity modulation using the second grid 14, and detected by a fringe scanning method, for example. In the fringe scanning method, the second grid 14 is translationally moved in the X direction relative to the first grid 13 by a scan pitch, which is an integral submultiple of the grid pitch e.g. one-fifth of the grid pitch in a direction along a grid surface with respect to the X-ray focus. While the second grid 14 is moved, the X-ray beam is applied from the X-ray source 11 to the test object H, and the X-ray image detector 15 detects an image more than once. Thereby, a differential phase image (corresponding to angular distribution of the X-ray beam refracted by the test object H) is obtained from a phase shift amount (a shift amount in phase between the presence and the absence of the test object H) of pixel data of each pixel of the X-ray image detector 15. Integrating the differential phase image along a fringe scanning direction allows obtainment of the phase contrast image.

As described above, the colloidal gold particles are used in the X-ray absorbing portions of the grids according to this embodiment. The gold colloidal particle contains the plural types of X-ray absorptive metals such as bismuth in addition to gold, and shows high X-ray absorptivity. Also, since the colloidal gold particles with low stress are used as the X-ray absorbent material 23, the grids are flexible and resistant to the external force. Furthermore, according to the manufacturing method of the present invention, the grid is manufactured in a shorter time and at lower cost than those in the case of embedding the X-ray absorbent material 23 into the grooves 22 by plating or the like. In the case of plating, since a seed layer is required in the bottom of each groove as an electrode, the grid has complicated configuration. However, the grid of this embodiment does not need the seed layer, and has simple configuration. Moreover, the charge defect of the X-ray absorbent material 23 such as the sticking, void, and shim is appropriately prevented. Therefore, the high performance grid is obtained.

In the above embodiment, the configuration, manufacturing method, effect, and the like of the second grid 14 are described, but the same goes for the source grid 12 and the first grid 13. The X-ray absorbing portions of the source grid 12 and the first grid 13 have an aspect ratio lower than that of the second grid 14. Thus, the number of charging the colloidal gold solution becomes smaller in the source grid 12 and the first grid 13 than that in the second grid 14. Note that, the colloidal gold particles are sensitive to heat. Therefore, if the source grid 12 becomes hot by irradiation with the X-ray beam, the grid of this embodiment should not be used as the source grid 12.

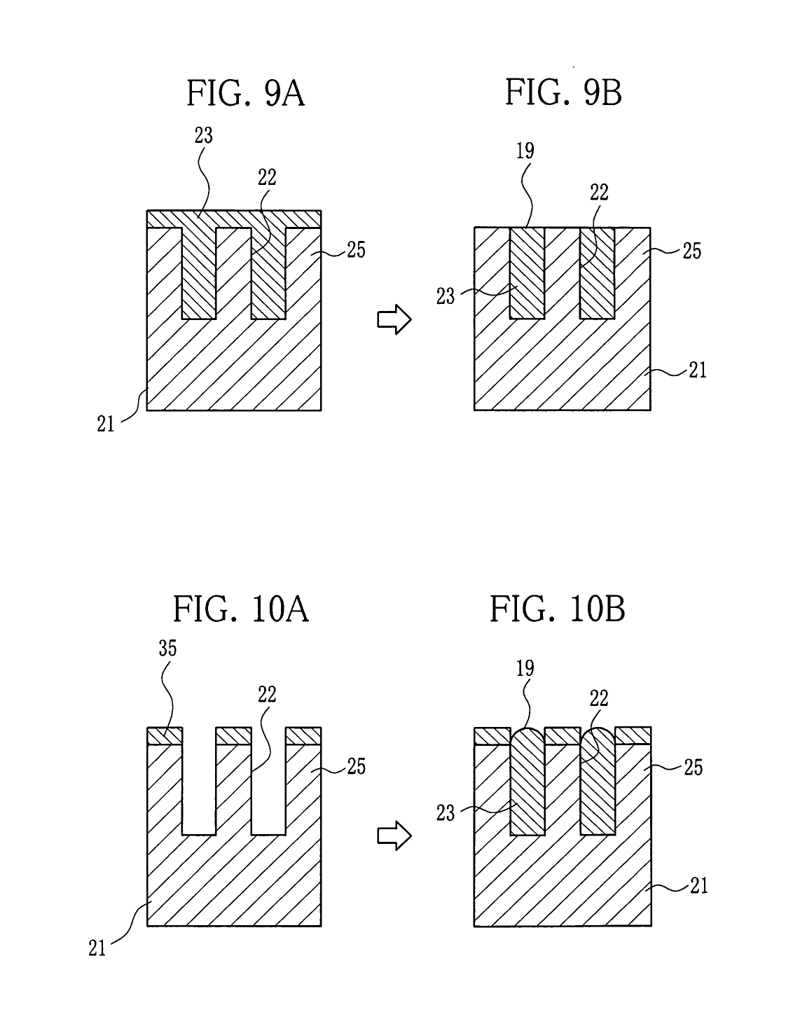

To sufficiently charge the X-ray absorbent material 23 into the grooves 22 with the high aspect ratio by application of the colloidal gold solution 30, the X-ray absorbent material 23 has to be deposited on the top surface of the X-ray transparent substrate 21, as shown in FIG. 9A. However, if the partition walls 25 functioning as the X-ray transmitting portions are covered with the X-ray absorbent material 23, the performance of the grid is degraded. In such case, as shown in FIG. 9B, the X-ray absorbent material 23 laid on the top surface of the X-ray transparent substrate 21 is preferably removed using CMP (Chemical Mechanical Polishing) or the like.

As shown in FIG. 10A, a liquid repellent film 35 made of Teflon (trademark) or the like, which is repellent to the colloidal gold solution 30, may be provided in advance on the top surface of the X-ray transparent substrate 21. In this case, since the liquid repellent film 35 repels the colloidal gold solution 30, as shown in FIG. 10B, the X-ray absorbent material 23 is not laid on the top surface of the X-ray transparent substrate 21. Thus, the performance of the grid is not degraded. The liquid repellent film 35 may be removed after formation of the X-ray absorbing portions 19, or may be left as is.

In the above embodiment, the same type of colloidal gold solution 30 is applied over several times. However, different types of colloidal gold solutions may be applied in accordance with the number of occasions of the application. For example, in a first application, a colloidal gold solution of low viscosity may be used to ease the flow of the colloidal gold solution into the bottom of each groove 22. The colloidal gold solution of the low viscosity refers to, for example, a colloidal gold solution containing colloidal gold particles with a small diameter, a colloidal gold solution with a low content of colloidal gold particles, or the like. In a second or later application, a colloidal gold solution with a high content of colloidal gold particles may be used to lower a reduction amount of the colloidal gold solution by heating and drying and improve throughput. In another case, two or more types of colloidal gold solutions having different viscosities, different particle diameters, and/or different percentages of particle content may be applied alternately or in turn. In further another case, different types of colloidal metal solutions may be applied alternately or in turn.

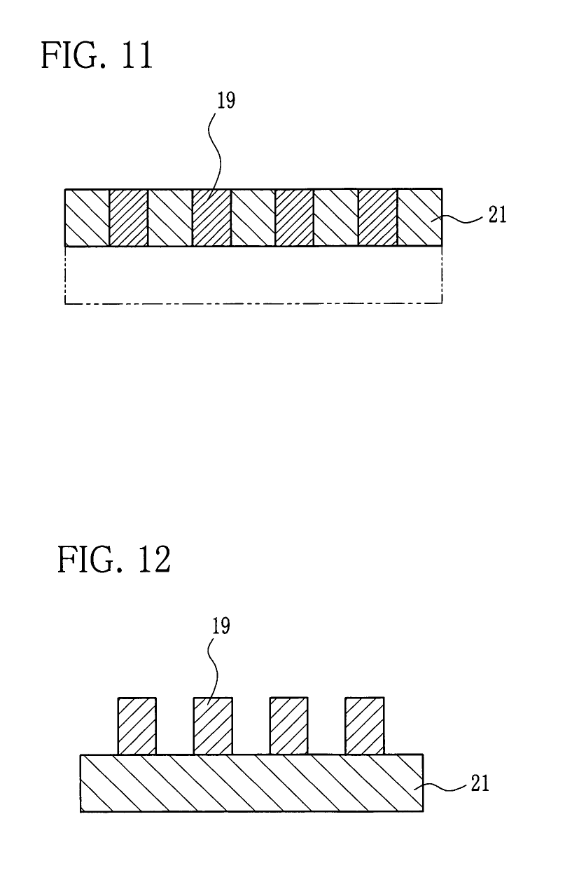

As shown in FIG. 11, a rear surface of the X-ray transparent substrate 21 may be polished and thinned by the CMP or the like, after formation of the X-ray absorbing portions 19. In another case, as shown in FIG. 12, the X-ray transparent substrate 21 may be removed at portions between the X-ray absorbing portions 19 by etching or the like, after formation of the X-ray absorbing portions 19. The X-ray transparency of the grid is improved in either case.

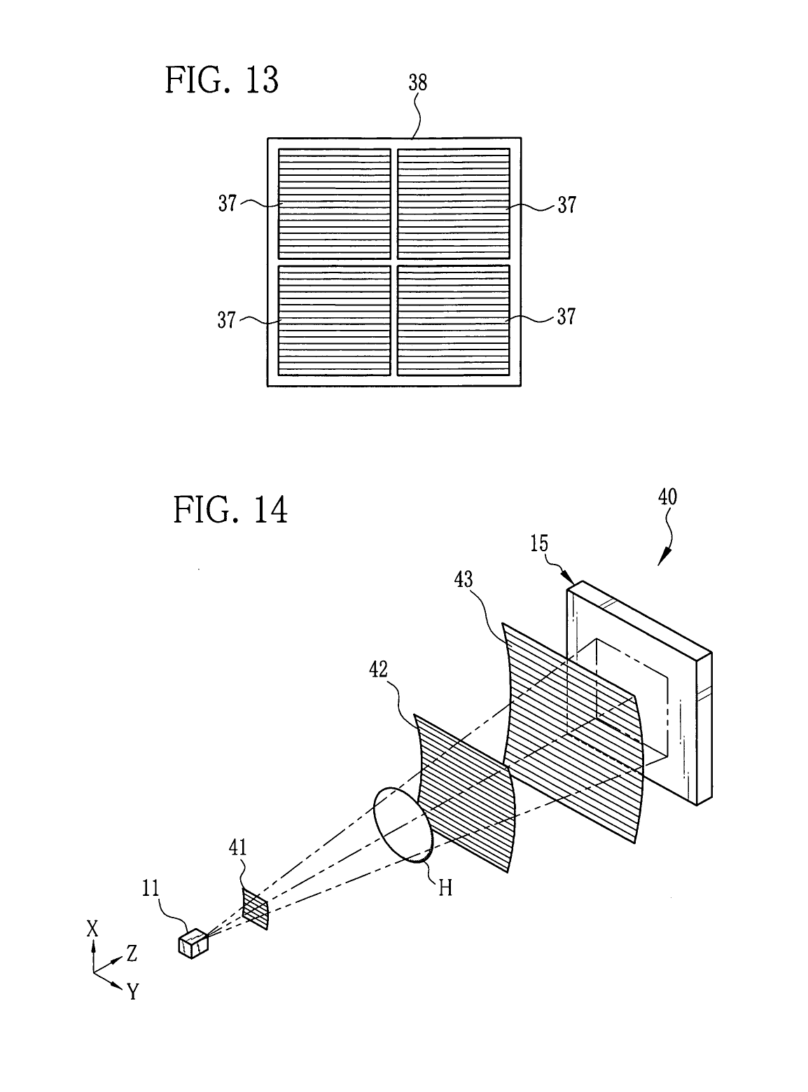

If the size of a grid manufacturable in the present invention is small, a plurality of small-sized grids 37 may be arranged in a tiled manner, as shown in FIG. 13, to compose a single large-sized grid 38. As shown in an X-ray imaging system 40 of FIG. 14, a grid of the present invention may be applied to a convergence source grid 41, a convergence first grid 42, and a convergence second grid 43, which are curved concavely along an extending direction of the X-ray absorbing portions to reduce vignetting of the cone-shaped X-ray beam. The grid of the present invention is flexible and resistant to damage during flexion, owing to use of the colloidal gold particles with low stress as the X-ray absorbent material 23.

Furthermore, in the above embodiment, the colloidal gold solution 30 is charged into the grooves 22 using capillarity. The colloidal gold solution 30 may be directly dripped into the grooves 22 using an inkjet head that can eject a droplet roughly the size of the width of the groove 22.

Colloidal particles used as the X-ray absorbent material 23 are not limited to colloidal metal particles such as gold, but may be colloidal non-metal particles. The same or similar effect can be obtained even with the use of colloidal particles made of a radiation absorptive inorganic material including, for example, Gd₂O₂S, CsI, Bi₂MO₂₀ (M: Ti, Si, Ge), Bi₂WO₆, Bi₂₄B₂O₃₉, ZnTe, PbO, Hgi, PbI₂, CdS, CdSe, BiI₃, CdTe, and the like.

In the above embodiment, the first and second grids 13 and 14 linearly project the X-ray beam passed therethrough. However, a grid of the present invention may be applied to configuration in which a grid diffracts an X-ray beam and causes the so-called Talbot effect (refer to U.S. Pat. No. 7,180,979 and Applied Physics Letters Vol. 81, No. 71, page 3287, written by C. David et al. on October 2002). Note that, in this case, the second grid 14 has to be located at the Talbot distance from the first grid 13. Also, in this case, a phase grid may be used as the first grid 13, and the phase grid projects a fringe image (self image) occurring by the Talbot effect to the second grid 14. Instead of the X-ray beam, a laser beam is available (refer to Applied Optics, Vol. 37, No. 26, page 6227, written by Hector Canabal et al. on September 1998.)

The above embodiments are described by taking the X-ray beam as an example of radiation, but the present invention is applicable to a grid used with radiation including α-rays, β-rays, γ-rays, an electron beam, ultraviolet rays, and the like. The present invention is also applicable to an anti-scatter grid, which removes the radiation scattered by the test object when passing through the test object. Furthermore, the above embodiments may be combined with each other as long as no contradiction arises.

Although the present invention has been fully described by the way of the preferred embodiment thereof with reference to the accompanying drawings, various changes and modifications will be apparent to those having skill in this field. Therefore, unless otherwise these changes and modifications depart from the scope of the present invention, they should be construed as included therein.

What is claimed is:

1. A grid for radiography comprising:
a plurality of radiation absorbing portions made of colloidal radiation absorptive particles; and
a plurality of radiation transmitting portions for passing radiation.

2. The grid according to claim 1, wherein said colloidal radiation absorptive particles are embedded in a plurality of grooves provided in a radio-transparent substrate.

3. The grid according to claim 2, further comprising:
a plurality of bridge portions for connecting two or more partition walls, each of said partition walls being provided between said grooves as a partition.

4. The grid according to claim 1, wherein said radiation absorbing portions are provided on a radio-transparent substrate.

5. The grid according to claim 1, wherein said colloidal radiation absorptive particles are colloidal metal particles or colloidal non-metal inorganic particles.

6. A manufacturing method of a grid for radiography comprising the steps of:
forming a plurality of grooves and a plurality of bridge portions in a radio-transparent substrate, each of said bridge portions connecting two or more partition walls provided as a partition between said grooves;
charging a colloidal solution containing colloidal radiation absorptive particles into said grooves without overflowing said grooves;
heating said substrate at least at a portion of said grooves charged with said colloidal solution, and drying said colloidal solution to leave said colloidal radiation absorptive particles behind in said grooves; and
repeating said charging step and said heating step, until said grooves are filled with said colloidal radiation absorptive particles.

7. The manufacturing method according to claim 6, wherein in said charging step, said colloidal solution is applied to said substrate in such an amount as not to overflow said grooves, so that all said colloidal solution flows into said grooves.

8. The manufacturing method according to claim 7, further comprising the step of:
after said forming step of said grooves and said bridge portions, subjecting said substrate to a chemical treatment to improve wettability of said substrate.

9. The manufacturing method according to claim 6, wherein in said heating step, a laser beam is applied to said substrate at a rear surface opposite to a front surface formed with said grooves.

10. The manufacturing method according to claim 6, wherein between said colloidal solution to be charged into said grooves for a first time and said colloidal solution to be charged into said grooves for a second or later time, at least one of a viscosity, a diameter of said colloidal radiation absorptive particles, a percentage content of said colloidal radiation absorptive particles is different.

11. The manufacturing method according to claim 6, further comprising the step of:
after said colloidal radiation absorptive particles are deposited on said substrate by said repeating step, removing said colloidal radiation absorptive particles deposited on said substrate.

12. The manufacturing method according to claim 6, further comprising the step of:
after said forming step of said grooves and said bridge portions, forming a liquid repellent film on a front surface of said substrate to render said front surface repellent to said colloidal solution.

13. The manufacturing method according to claim 6, wherein said colloidal solution contains colloidal metal particles or colloidal non-metal inorganic particles.

14. A radiation imaging system comprising:
a radiation source for emitting radiation;
a first grid for producing a fringe image by passing said radiation;
a second grid for applying intensity modulation to said fringe image in each of plural relative positions having different phases with respect to a periodic pattern of said fringe image;
a third grid disposed between said radiation source and said first grid, for partly shielding said radiation emitted from said radiation source to form a plurality of linear light sources; and
a radiation image detector for detecting said fringe image after being subjected to said intensity modulation by said second grid in each of said relative positions; and
wherein at least one of said first to third grids includes:
a plurality of radiation absorbing portions made of colloidal radiation absorptive particles; and
a plurality of radiation transmitting portions for passing said radiation.
